(19) United States
(12) Patent Application Publication
(10) Pub. No.: US 2010/0110860 A1
(43) Pub. Date: May 6, 2010

(54) DATA STORAGE MEDIA CONTAINING MAGNESIUM METAL LAYER

(75) Inventors: Douglas P. Hansen, Spanish Fork, UT (US); Matthew R. Linford, Orem, UT (US)

Correspondence Address: Pepper/Millenniata, 50th Floor, 500 Grant Street, Pttsburgh, PA, 15219-2502, US

(73) Assignee: BRIGHAM YOUNG UNIVERSITY, Provo, UT (US)

(21) Appl. No.: 12/611,039

(22) Filed: Nov. 2, 2009

Related U.S. Application Data
(60) Provisional application No. 61/198,103, filed on Nov. 3, 2008.

(51) Int. Cl. G11B 7/00; B32B 3/02; C23C 16/06; C23C 14/34; C23C 14/14

(52) U.S. Cl. 369/100; 428/64.4; 428/65.1; 428/64.7; 427/250; 204/192.15; 427/597; G9B/7

(57) ABSTRACT

Optical information media containing a magnesium metal layer and a reactive material layer are disclosed. The magnesium metal can react directly with the reactive material layer, or with a chemical evolved from the reactive material layer after application of energy from a source such as a laser.

### CROSS REFERENCE TO RELATED APPLICATIONS

The present application claims priority to U.S. Provisional Patent Application Ser. No. 61/198,103 filed Nov. 3, 2008, the contents of which are incorporated herein by reference.

### FIELD OF THE INVENTION

The invention relates to long-term digital data storage media, and more specifically, to materials and manufacturing processes that produce very stable digital data storage media. In particular, an optical disc containing a magnesium layer and a reactive layer is disclosed.

### DESCRIPTION OF RELATED ART

One of the major issues with data archiving is media longevity. The data storage methods used today are insufficient for data storage beyond 50 years, 100 years, or longer. This longevity dilemma, as seen from the archivist's point of view, has many facets and equally many plausible, but unfortunately flawed potential solutions. For example, one method of perceived long-term data storage is optical digital data storage discs. Optical digital data storage comes in many capacities and formats, including, but not limited to the disc capacities of compact disc (CD), Mini-Disc, digital video disc (DVD), high-definition (HD), and BLU-RAY DISC® (BD) with dozens of format variations within each disc capacity, the most common including, for example, R, +R, −RW, +RW, and RAM, to name a few. Given the nature of the construction of these media, they appear impervious to aging and often carry long-life expectancy claims. Unfortunately, experimental data on the life expectancy of these media types contradicts the generous life estimates provided by some manufacturers. (See, for example, Stability Comparison of Recordable Optical Discs—A Study of Error Rates in Harsh Conditions, J. Res. Natl. Inst. Stand. Technol. 109, 517-524 (2004)).

Another frequently attempted solution for solving the longevity dilemma for long-term (typically greater than 5-7 years) retention and storage of digital data is to preserve data on magnetic media such as tape or a hard disk, and then to renew the stored data by re-copying the data onto a new tape, hard drive or optical storage disc on a periodic basis. Variations on this theme can be played using optical data storage technology of various data densities and formats. While certain searchability issues may be mitigated by data transition to optical format, continually re-writing previously archived data is not a workable solution. Transferring archival data from one volatile format to another of similar or even greater susceptibility is error prone and inherently risky. (See, for example, “Storage expert warns of short life span for burned CDs,” John Blau, Computerworld Magazine, Jan. 10, 2006.) Cost is another facet of the problem. Initially, archiving the amount of data generated by a company or other entity during any particular year may not be difficult or costly, but archival costs compound exponentially as the data from preceding years is repeatedly re-written to new media in addition to the integration of any new data.

The search for a solution to the longevity dilemma has led to the creation of new data storage technologies that focus on increasing a system's data storage recording rate and data density. Examples include: Oriented Nano-Structure (see U.S. Patent Application 2007/0195672 (published Aug. 23, 2007)), holographic (See U.S. Patent Application 2007/0216981 (published Sep. 20, 2007)), and multi-layer technology (See U.S. Patent Application 2007/0242592 (published Oct. 18, 2007)). In each case, the focus is on significantly higher data storage densities: approximately 150 gigabytes per disc for Oriented Nano-Structure, greater than 250 gigabytes per disc for holographic and approximately one terabyte per disc for multi-layer media technology. Furthermore, as will be discussed herein, neither expanded data capability, nor increased recording speeds have positively impacted this problem.

One issue with the technology path described above is that the new media capacities and formats suffer from the same age-degradation effects as the older media capacities and formats. The write methods embodied in the aforementioned technologies write the data in a similar means and use materials that are nearly identical to that of previous technology generations. The one significant change with each succeeding generation has been smaller feature sizes, which permit higher data densities, but also exacerbates age-degradation effects.

When introduced in 1964, writeable optical data storage devices used lasers to record an analog-wave signal in an ablatable write layer, usually made of a thin layer of aluminum or rhodium, on a MYLAR®-substrate filmstrip. (See, for example, U.S. Pat. No. 3,314,073). Unwritten portions were reflective and written portions were absorptive or transmissive to a read laser. Later patents by the same inventors suggested encoding digital holes in the ablatable layer (see, for example, U.S. Pat. No. 3,474,457), mounting the media on a drum (see, for example, U.S. Pat. No. 3,654,624), and increasing read and write reliability by adding surface defect and error checking (see, for example, U.S. Pat. No. 3,657,707). These high-energy data storage designs suffered in part because “[i]n selectively burning thick metal layer storage media with modulated laser energy, there is a tendency to burn or destroy the substrate on which the film or metal layer is coated.” (See U.S. Pat. No. 3,665,483, column 3). The writing methods suggested by these early patents had the further disadvantage of depositing the ablative metal material on the writing optics, thereby effectively contaminating the write system.

Most CD and DVD−/+R formats today include low bleachable-energy dyes. The writing process occurs when a write laser increases the dye's internal energy to such a point that an irreversible chemical reaction occurs that either bleaches the dye, making the dye transparent, or “burns” the dye, making the dye more opaque to a read laser. Optical disc manufacturers select dyes, in part, for their ability to be easily bleached or burned at relatively low activation energies. These low bleachable-energy dyes suffer from the same or greater age degradation kinetics as those described above. Discs manufactured using these dyes may become unreadable in as few as three to five years. Hence, existing, low-energy melting or bleaching write processes make most modern optical media inappropriate as an archiving medium. Write layers requiring little energy to record an optical mark also require little energy to modify unwritten portions by natural chemical, thermal or environmental forces anytime after the initial recording.

Most commercial CD, DVD, and BD media use organic dyes in their data layer. In general, organic dyes are widely available and inexpensive, but suffer from poor longevity. Dyes can be oxidized over time, losing their fluorescent properties. Dyes can also “bleach” after being excited by a laser. Bleaching chemically alters dyes such that they no longer function and are not detectable.

Ideally, to make an optical media disk suitable for archive purposes, the materials, write methods, and manufacturing processes preferably have significant immunity to thermal and chemical kinetic aging processes. In addition, the materials are preferably not subject to the age degradation effects that may eventually cause chemical or mechanical breakdown. The write process preferably requires sufficient energy such that the write layers' written portions are permanently modified and the unwritten portions are not and will not be easily modified through aging or other deterioration processes. Thus, in an ideal media, the write layer is permanently modified as written portions are completely ablated or removed and unwritten portions are not removable or changeable except through high-power writing processes.

Despite the many reported developments in optical information media, there still exists a need for new materials and methods.

### SUMMARY OF THE INVENTION

Optical information media containing a magnesium metal layer and a reactive material layer are disclosed. The reactive material layer either directly reacts with the magnesium metal, or evolves a chemical that reacts with the magnesium metal upon application of energy to the reactive material layer.

### DESCRIPTION OF THE FIGURES

The following figures form part of the present specification and are included to further demonstrate certain aspects of the present invention. The invention may be better understood by reference to one or more of these figures in combination with the detailed description of specific embodiments presented herein.

FIG. 1 shows an optical information medium having a support substrate, a reactive material layer, and a magnesium metal layer.

FIG. 2 shows an optical information medium having a support substrate, one or more intervening layers, a reactive material layer, and a magnesium metal layer.

FIG. 3 shows an optical information medium having a support substrate, a reactive material layer, a magnesium metal layer, and a reflective layer.

FIG. 4 shows an optical information medium having a first support substrate, a reactive material layer, a magnesium metal layer, and a second support substrate.

FIG. 5 shows an optical information medium having a first support substrate, a reactive material layer, a magnesium metal layer, a reflective layer, and a second support substrate.

FIG. 6 shows an optical information medium having an external protection layer, a support substrate, a reactive material layer, and a magnesium metal layer.

FIG. 7 shows an optical information medium having a first support substrate, a gas diffusion barrier layer, a reactive material layer, a magnesium metal layer, a reflective layer, and a second support substrate.

FIG. 8 shows an optical information medium having a first external protection layer, a first support substrate, a gas diffusion barrier layer, a reactive material layer, a magnesium metal layer, a reflective layer, a second support substrate, and a second external protection layer.

FIG. 9 shows an optical information medium having a support substrate, a reactive material layer, a magnesium metal layer, and an antireflective layer.

FIG. 10 shows an optical information medium having a support substrate and a magnesium metal layer in direct facial contact.

### DETAILED DESCRIPTION OF THE INVENTION

While compositions and methods are described in terms of “comprising” various components or steps (interpreted as meaning “including, but not limited to”), the compositions and methods can also “consist essentially of” or “consist of” the various components and steps. The “consist essentially” of or “consist of” terminology should be interpreted as defining essentially closed-member groups.

Materials

One embodiment of the present invention comprises an optical information medium suitable for archival purposes. The materials and manufacturing processes are designed to be very durable and not subject to age-degradation effects to a substantial degree. Likewise, the information writing process is intended to be permanent and not subject to age degradation effects to a substantial degree.

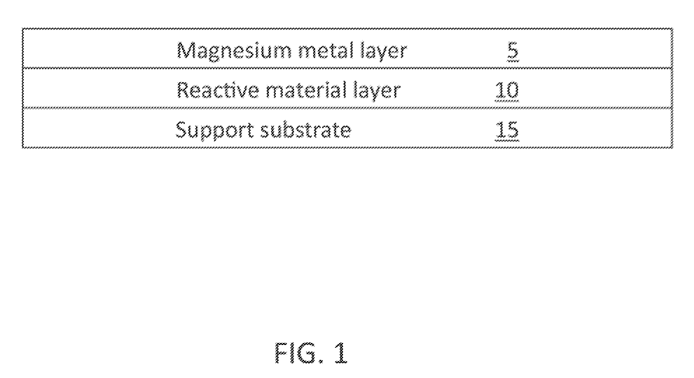

As shown in FIGS. 1-10, the medium comprises at least one magnesium metal layer 5, at least one reactive material layer 10, and at least one support substrate 15. The magnesium metal layer 5 and the reactive material layer 10 preferably facially contact each other.

The optical information medium can generally be of any shape and size. A currently preferred shape is a flat, round disc. Other shapes include a drum or a linear tape. Currently envisioned sizes are about 8 cm diameter, about 12 cm diameter (like a conventional CD or DVD), about 13 cm diameter, about 20 cm diameter, about 10 inch (about 25.4 cm) diameter, about 26 cm diameter, and about 12 inch (about 30.48 cm) diameter.

A cross-section view of the optical information medium can be symmetrical or asymmetrical. In numerous embodiments, the cross-section is asymmetrical.

The magnesium metal layer 5 comprises, consists essentially of, or consists of magnesium metal (Mg). Small amounts of magnesium oxide or other magnesium materials may be produced during production of the magnesium metal layer 5, but will not significantly impact performance of the layer. The small amount of such magnesium materials may exist as a monolayer or several monolayers at the interface of the magnesium metal layer 5 and the reactive material layer 10.

The magnesium metal layer 5 can generally be of any thickness. A lower thickness limit can be about 1 nm, about 5 nm, or about 10 nm. An upper thickness limit can be about 200 nm, about 250 nm, or about 300 nm. Example thicknesses are about 1 nm, about 5 nm, about 10 nm, about 20 nm, about 30 nm, about 40 nm, about 50 nm, about 60 nm, about 70 nm, about 80 nm, about 90 nm, about 100 nm, about 120 nm, about 140 nm, about 160 nm, about 180 nm, about 200 nm, about 250 nm, about 300 nm, and ranges between any two of these values.

The reactive material layer 10 comprises, consists essentially of, or consists of at least one material that either reacts with magnesium metal upon application of sufficient energy, or at least one material that evolves a chemical that reacts with magnesium metal upon application of energy. Examples of materials that react with magnesium metal include, but are not limited to, oxygenated hydrocarbons, polyvinyl alcohol, polycarbonate, poly(methylmethacrylate), poly[(methylmethacrylate)-co-(Disperse Red 1 methacrylate)], poly(methyl acrylate), poly(maleic acid), poly(DL-lactide), poly(propylene carbonate), poly(acrylic acid-co-maleic acid), sugar, monosaccharide, polysaccharide, glucose, sucrose, lactose, D-glucuronic acid, sorbitol, cellulose, and nitrocellulose. Evolved chemicals that can react with magnesium metal include, but are not limited to, carbon dioxide, carbon monoxide, ethanol, methanol, acetic acid, formic acid, dimethyl ether, and water. Materials that evolve such chemicals include oxygenated polymers such as, for example, the materials listed above. In some embodiments, energy would be applied by use of a laser.

Magnesium can react with a variety of materials to effect an optically detectable change in the magnesium material layer. The following are examples of specific chemicals that can react with magnesium. Magnesium exothermically reacts with carbon dioxide according to the equation: 2Mg+CO₂=>2MgO+C. This reaction has a ΔG value of −744.2 kJ/mol. Magnesium exothermically reacts with formic acid according to the equation: 3Mg+2HCO₂H=>2MgO+C₂H₂+Mg(OH)₂. This reaction has a ΔG value of −1401 kJ/mol. Magnesium exothermically reacts with acetic acid according to the equation: 3Mg+2CH₃CO₂H=>2MgO+CH₃CCCH₃+Mg(OH)₂. This reaction has a ΔG value of −1397 kJ/mol. Magnesium exothermically reacts with dimethyl ether according to the equation: Mg+CH₃OCH₃=>MgO+C₂H₆. This reaction has a ΔG value of −488.7 kJ/mol. Magnesium exothermically reacts with methanol according to the equation: Mg+CH₃OH=>Mg(OH)₂+C₂H₆. This reaction has a ΔG value of −699.1 kJ/mol.

The reactive material layer 10 can generally be of any thickness. A lower thickness limit can be about 1 nm. An upper thickness limit can be about 50 nm or about 100 nm. Example thicknesses are about 1 nm, about 5 nm, about 10 nm, about 15 nm, about 20 nm, about 30 nm, about 40 nm, about 50 nm, about 60 nm, about 70 nm, about 80 nm, about 90 nm, about 100 nm, and ranges between any two of these values.

The support substrate 15 can generally be any material compatible with use in optical information storage, such as, for example, polymers or ceramic materials having desirable optical and mechanical properties. Support substrates can comprise polycarbonate, polystyrene, aluminum oxide, polydimethyl siloxane, polymethylmethacrylate, silicon oxide, glass, aluminum, stainless steel, or mixtures thereof. If substrate transparency is not desired, metal substrates may be used as a support substrate. Optically transparent plastics or polymers may also be used. Support substrates can be selected from materials having sufficient rigidity or stiffness. Stiffness is commonly measured as Young's modulus in units of pressure per unit area, and preferably is about 0.5 GPa to about 70 GPa. Specific examples of stiffness values are about 0.5 GPa, about 1 GPa, about 5 GPa, about 10 GPa, about 20 GPa, about 30 GPa, about 40 GPa, about 50 GPa, about 60 GPa, about 70 GPa, and ranges between any two of these values. Support substrates can be selected from materials having an index of refraction of about 1.45 to about 1.70. Specific examples of an index of refraction include about 1.45, about 1.5, about 1.55, about 1.6, about 1.65, about 1.7, and ranges between any two of these values.

The support substrate 15 preferably comprises materials that are not subject to age degradation effects. Presently preferred materials are polycarbonate and silicon oxide (fused silica).

The support substrate 15 can generally be of any thickness. The substrate thickness can be selected as a function of the drive capacity. For example, 1.2 millimeter-thick substrates are compatible with CD drives, 0.6 millimeter-thick substrates are compatible with DVD drives, and 0.1 millimeter-thick substrates are compatible with BD drives.

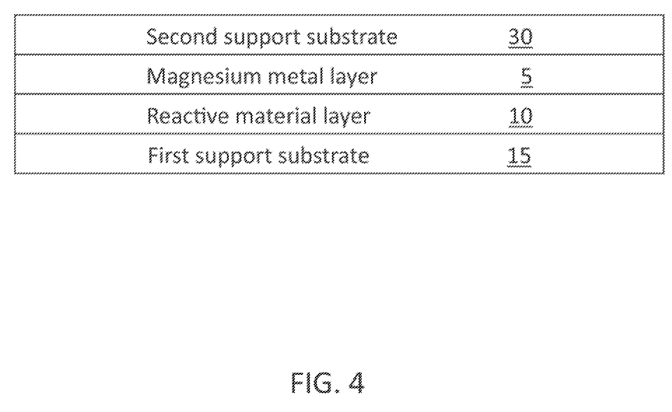

The optical information medium can comprise a first support substrate 15 and a second support substrate 30, as shown in FIG. 4. The first support substrate 15 and second support substrate 30 can be made of the same material, or can be made of different materials. In some embodiments, the first support substrate 15 and the second support substrate 30 are oriented such that they form the outer two layers of the optical information medium (i.e., are the first and last layers when viewed as a cross section). This is especially true in a DVD-type format.

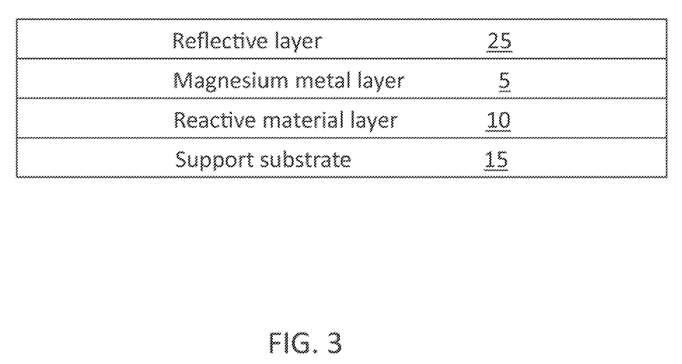

The optical information medium can further comprise at least one reflective layer 25. The reflective layer 25 materials are selected for their extreme durability and reflectivity and may comprise materials such as, for example, silicon, silver, titanium, chromium, platinum, rhodium, gold, aluminum, or alloys thereof. The reflective layer 25 can be oriented such that it is between the support substrate 15 and the reactive material layer 10, or away from both the support substrate 15 and the magnesium metal layer 5. In the first case, a cross section would first intersect the support substrate 15, then the reflective layer 25, then the reactive material layer 10, then the magnesium metal layer 5. In the second case, a cross section would first intersect the support substrate 15, then the reactive material layer 10, then the magnesium metal layer 5, then the reflective layer 25. An example of such a structure is shown in FIG. 3. In this figure, the reflective layer 25 facially contacts the magnesium metal layer 5, but does not facially contact the reactive material layer 10.

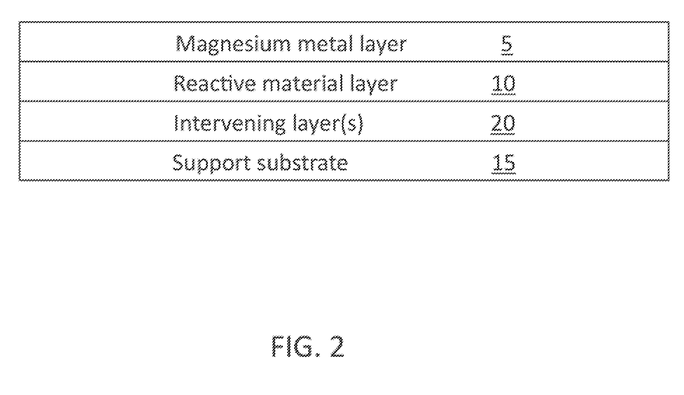

The reactive material layer 10 can facially contact the support substrate 15, and the magnesium metal layer 5 can facially contact the reactive material layer 10. This arrangement is shown in FIG. 1. Alternatively, at least one intervening layer 20 can be oriented between the support substrate 15 and the reactive material layer 10, as shown in FIG. 2.

The optical information medium of the invention can further comprise at least one intervening layer 20 oriented between any two of the other layers. For example, an intervening layer 20 can be oriented between the support substrate 15 and the reactive material layer 10. In other embodiments, an intervening layer 20 can be oriented between the magnesium metal layer 5 and the reflective layer 25.

An example of an intervening layer 20 is a gas diffusion barrier layer 40. Gas diffusion barrier layers 40 can be made of a variety of materials such as, for example, silicon oxide, aluminum oxide, glass, ceramics, or other vitreous materials.

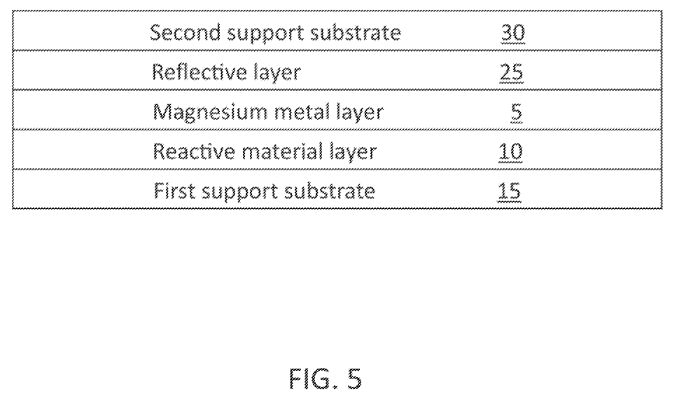

The magnesium metal layer 5 and reactive material layer 10 can be “sandwiched” between two support substrates (a first support substrate 15 and a second support substrate 30). An example of this is shown in FIG. 4. In this figure, a cross section would first intersect the first support substrate 15, then the reactive material layer 10, then the magnesium metal layer 5, then the second support substrate 30. A more complicated example is shown in FIG. 5, where a reflective layer 25 is added between the magnesium metal layer 5 and the second support substrate 30. In this figure, a cross section would first intersect the first support substrate 15, then the reactive material layer 10, then the magnesium metal layer 5, then the reflective layer 25, then the second support substrate 30.

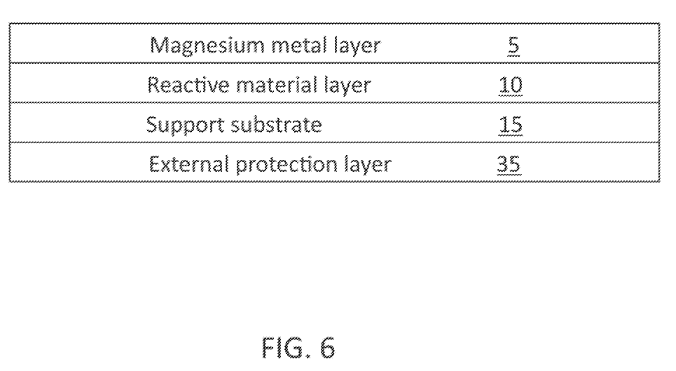

The optical information medium can further comprise at least one external protection layer 35. The external protection layer 35 can facially contact the support substrate 15, oriented away from the reactive material layer 10 and the magnesium metal layer 5. In such an arrangement, the external protection layer 35 would form an outer coating, thereby protecting the optical information medium against external forces or materials. A cross section would first intersect the external protection layer 35, then the support substrate 15, then the reactive material layer 10, then the magnesium metal layer 5. This embodiment of the invention is shown in FIG. 6.

The optical information medium can further comprise at least one antireflective layer 50. Antireflective materials are widely used in the photoresist market. Antireflective layers 50 behave by scattering light and/or absorbing light, rather than reflecting it. Examples of antireflective layers 50 are aluminum chromium alloy, titanium nitride, metal nitride, or a metal silicon nitride (as described in U.S. Pat. No. 6,614,085 (issued Sep. 2, 2003), which is herein incorporated by reference to the extent such reference is not inconsistent with the explicit teachings of this specification.)

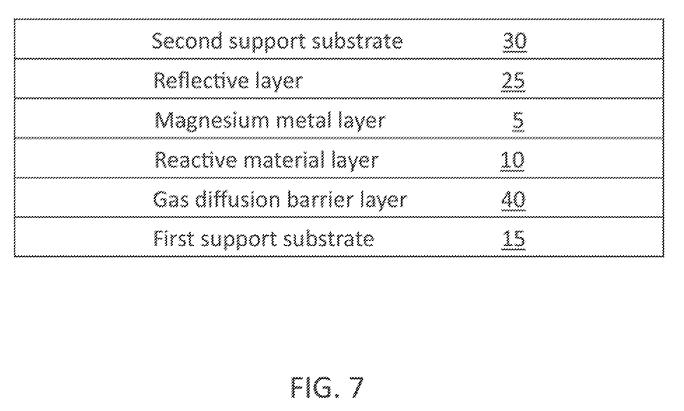

One embodiment of an optical information medium can comprise, consist essentially of, or consist of: a first support substrate 15, a gas diffusion barrier layer 40, a reactive material layer 10, a magnesium metal layer 5, a reflective layer 25, and a second support substrate 30. This embodiment is shown in FIG. 7. The first support substrate 15 facially contacts the gas diffusion barrier layer 40, the gas diffusion barrier layer 40 facially contacts the reactive material layer 10, the reactive material layer 10 facially contacts the magnesium metal layer 5, the magnesium metal layer 5 facially contacts the reflective layer 25, and the reflective layer 25 facially contacts the second support substrate 30. A cross section would first intersect the first support substrate 15, then the gas diffusion barrier layer 40, then the reactive material layer 10, then the magnesium metal layer 5, then the reflective layer 25, then the second support substrate 30.

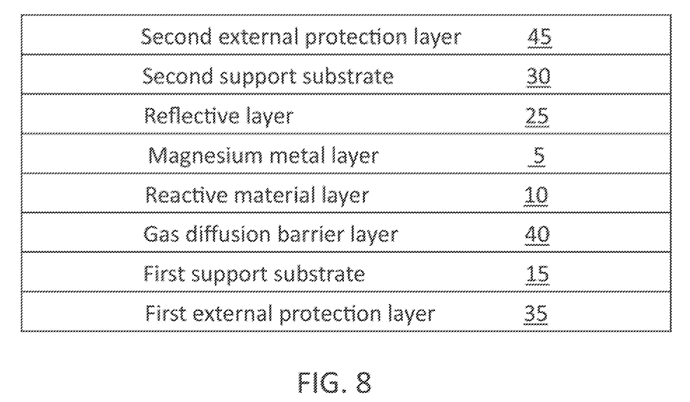

Another embodiment of an optical information medium can comprise, consist essentially of, or consist of: a first external protection layer 35, a first support substrate 15, a gas diffusion barrier layer 40, a reactive material layer 10, a magnesium metal layer 5, a reflective layer 25, a second support substrate 30, and a second external protection layer 45. This embodiment is shown in FIG. 8. The first external protection layer 35 facially contacts the first support substrate 15, the first support substrate 15 facially contacts the gas diffusion barrier layer 40, the gas diffusion barrier layer 40 facially contacts the reactive material layer 10, the reactive material layer 10 facially contacts the magnesium metal layer 5, the magnesium metal layer 5 facially contacts the reflective layer 25, and the reflective layer 25 facially contacts the second support substrate 30. A cross section would first intersect the first external protection layer 35, then the first support substrate 15, then the gas diffusion barrier layer 40, then the reactive material layer 10, then the magnesium metal layer 5, then the reflective layer 25, then the second support substrate 30, then the second external protection layer 45.

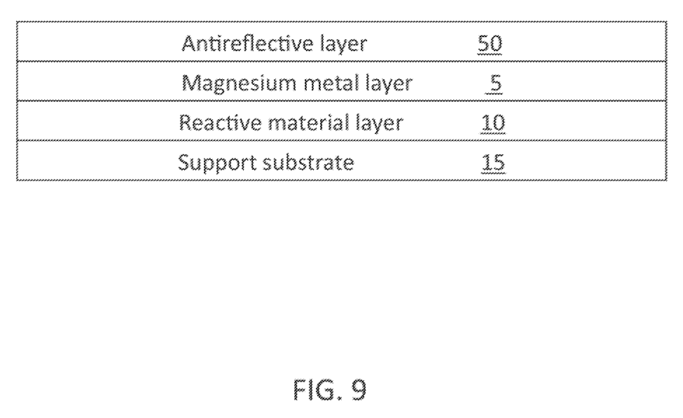

Yet another embodiment of an optical information medium can comprise, consist essentially of, or consist of: a support substrate 15, a reactive material layer 10, a magnesium metal layer 5, and an antireflective layer 50. The support substrate 15 facially contacts the reactive material layer 10, the reactive material layer 10 facially contacts the magnesium metal layer 5, and the magnesium metal layer 5 facially contacts the antireflective layer 50. This is shown in FIG. 9. In this figure, a cross section would first intersect the support substrate 15, then the reactive material layer 10, then the magnesium metal layer 5, then the antireflective layer 50. The presence of an antireflective layer 50 will increase the contrast between unreacted magnesium layer portions and magnesium layer portions that have reacted with the reactive material layer 10 (or chemicals evolved from the reactive material layer 10).

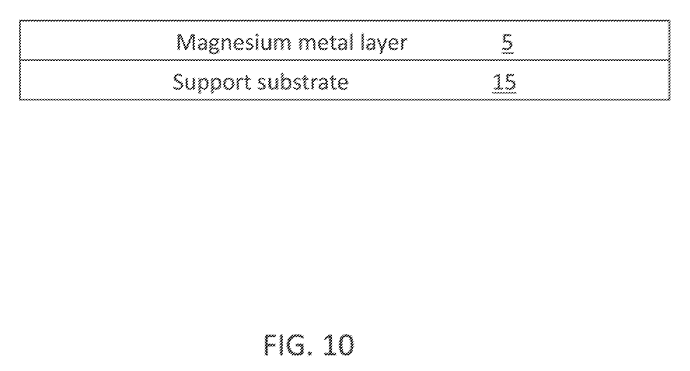

An alternative embodiment of the invention relates to an optical information medium comprising a support substrate 15 and a magnesium metal layer 5, where the support substrate 15 and the magnesium metal layer 5 facially contact each other. This arrangement is shown in FIG. 10. In this embodiment, the support substrate 15 can act as both a support substrate 15 and a reactive material layer 10. In other words, the support substrate 15 and the reactive material layer 10 are the same layer. In certain embodiments, the support substrate 15 is made of a material that can react with the magnesium metal layer 5. Examples of such materials are organic polymers such as polycarbonate or the other oxygenated polymers listed herein.

Methods of Preparation

Additional embodiments of the invention are directed towards methods of preparing an optical information medium.

In one embodiment, the method can comprise providing a support substrate, applying a reactive material layer, and applying a magnesium metal layer. The layers can be applied such that the reactive material layer facially contacts the support substrate, and the magnesium metal layer facially contacts the reactive material layer. Performing this method could produce the optical information medium shown in FIG. 1.

In an alternative embodiment, the method can comprise providing a support substrate, applying at least one intervening layer, applying a reactive material layer, and applying a magnesium metal layer. The layers can be applied such that the intervening layer facially contacts the support substrate, the reactive material layer facially contacts the intervening layer, and the magnesium metal layer facially contacts the reactive material layer. Performing this method could produce the optical information medium shown in FIG. 2.

Another embodiment of the invention is directed towards a method comprising providing a support substrate, applying a reactive material layer such that the support substrate and the reactive material layer facially contact each other, applying a magnesium metal layer such that the reactive material layer and the magnesium metal layer facially contact each other, and applying a reflective layer such that the magnesium metal layer and the reflective layer facially contact each other. Performing this method could produce the optical information medium shown in FIG. 3.

Still another embodiment is directed towards a method comprising providing a first support substrate, applying a reactive material layer such that the first support substrate and the reactive material layer facially contact each other, applying a magnesium metal layer such that the reactive material layer and the magnesium metal layer facially contact each other, and applying a second support substrate such that the magnesium metal layer and the second support substrate facially contact each other. Performing this method could produce the optical information medium as shown in FIG. 4.

An alternative embodiment is directed towards a method comprising providing a first support substrate, applying a reactive material layer such that the first support substrate and the reactive material layer facially contact each other, applying a magnesium metal layer such that the reactive material layer and the magnesium metal layer facially contact each other, applying a reflective layer such that the magnesium metal layer and the reflective layer facially contact each other, and applying a second support substrate such that the reflective layer and the second support substrate facially contact each other. Performing this method could produce the optical information medium shown in FIG. 5.

Another embodiment of the invention is directed towards a method comprising providing a support substrate having a first face and a second face, applying an external protection layer such that the first face and the external protection layer facially contact each other, applying a reactive material layer such that the second face and the reactive material layer facially contact each other, and applying a magnesium metal layer such that the reactive material layer and the magnesium metal layer facially contact each other. Performing this method could produce the optical information medium as shown in FIG. 6.

An alternative embodiment is directed towards a method comprising providing a first support substrate, applying a gas diffusion barrier layer such that the first support substrate and the gas diffusion barrier facially contact each other, applying a reactive material layer such that the gas diffusion barrier layer and the reactive material layer facially contact each other, applying a magnesium metal layer such that the reactive material layer and the magnesium metal layer facially contact each other, applying a reflective layer such that the magnesium metal layer and the reflective layer facially contact each other, and applying a second support substrate such that the reflective layer and the second support substrate facially contact each other. Performing this method could produce the optical information medium shown in FIG. 7.

The applying step in numerous embodiments of the invention can comprise physical vapor deposition (such as, for example, sputtering, reactive sputtering, e-beam evaporation, and laser ablation of a target), or chemical vapor deposition.

Methods of Use

Any of the above described optical information mediums can be used to store digital data. Various embodiments of the invention are directed to a method that comprises providing an optical information medium comprising at least one support substrate, at least one magnesium metal layer, and at least one reactive material layer, and applying energy to sites in the medium to cause a detectable change in the magnesium metal layer. The method can further comprise detecting the change in the magnesium metal layer. Any of the above described optical information mediums can be used.

Applying energy to sites in the metal material layer can also locally generate sufficient heat to deform tracks in the support substrate. Deformed sites in the support substrate can be subsequently detected.

Lasers can be used in the applying energy step as well as in the detecting step. Main classes of lasers include gas, diode-pumped solid state, and diode lasers.

The following examples are included to demonstrate preferred embodiments of the invention. It should be appreciated by those of skill in the art that the techniques disclosed in the examples which follow represent techniques discovered by the inventor(s) to function well in the practice of the invention, and thus can be considered to constitute preferred modes for its practice. However, those of skill in the art should, in light of the present disclosure, appreciate that many changes can be made in the specific embodiments that are disclosed and still obtain a like or similar result without departing from the scope of the invention.

### EXAMPLES

### Example 1

### Materials

Polycarbonate blank discs are commercially available from a variety of sources such as Bayer MaterialScience AG (Leverkusen, Germany), General Electric Company (Fairfield, Conn.), and Teijin Limited (Osaka, Japan). Fused silica blank discs are commercially available from a variety of sources such as Corning Incorporated (Corning, N.Y.), Hoya Corporation (Tokyo, Japan), and Schott AG (Mainz, Germany).

The graphite target, 99.999%, was supplied by Kurt J. Lesker Company (Clariton, Pa.), Part No. EJTCXXX503A2, Lot No. VPU014000/4-7-08. The chromium target, 99.95%, was supplied by Kurt J. Lesker Company (Clariton, Pa.) Part No. EJTCXXX353A2, Lot No. L5791/D05/601713. The magnesium target, 99.95% was supplied by Plasmaterials, Inc. (Livermore, Calif.), Lot No. PLA18926.

Radio frequency (RF) sputtering was performed using a PVD 75 instrument (Kurt J. Lesker Company; Pittsburgh, Pa.). The system was configured with one RF power supply, three magnetron guns that can hold 3 inch (7.62 cm) targets, and facilities for two sputter gases. The targets were arranged in a sputter-up configuration. Shutters covered each of the three targets. Substrates were mounted on a rotating platen that can be heated up to 200° C. The rotating platen was positioned above the targets. Most of the experimentation was done with no active heating of the platen. With no active heating, the temperature of the platen gradually increases with increased sputtering time at 400 w until the temperature reaches a maximum about 60° C.-70° C. The maximum temperature is reached after about three hours. The initial temperature in the chamber prior to sputtering was typically about 27° C. Times, targets, and sputtering sources were varied as described in the following examples.

### Example 2

### Preparation of a Magnesium and Carbon Layered Disc (65)

A polycarbonate optical disc with no coatings on it, 120 mm in diameter and 0.6 mm thick was mounted on the platen in the PVD 75 instrument. To create a first layer on the disc, a carbon graphite target was sputtered for 1 hour with 98% (v/v) Ar and 2% (v/v) CO₂ as the sputter gas with the total Capman pressure maintained at 3 mtorr and the magnetron power set at 400 w RF. The Capman pressure is an instrumental parameter and the Capman pressure value is close to the pressure in the plasma chamber. The resulting carbon film was about 28 nm thick.

To form the second layer on the disc, a magnesium target was sputtered for 3 minutes with 100% (v/v) Ar as the sputter gas with the total Capman pressure maintained at 3 mtorr and the magnetron power set at 400 w RF. The resulting film was about 125 nm thick.

For the third and final layer on the disk, a chromium target was sputtered for 10 minutes with 100% (v/v) Ar as the sputter gas with the total Capman pressure maintained at 4 mtorr and the magnetron power set at 400 w RF. The resulting film was about 92 nm thick.

The resulting disc had a polycarbonate support substrate, a carbon and carbon dioxide reactive material layer, a magnesium layer, and a chromium reflective layer.

### Example 3

### Preparation of a Magnesium and Carbon Layered Disc (139)

A polycarbonate optical disc with no coatings on it, 120 mm in diameter and 0.6 mm thick was plasma cleaned (Harrick Plasma, model PDC-001, Ithaca, N.Y.) prior to being mounted on the platen in the PVD 75 instrument. For the first layer on the disk, a carbon graphite target was sputtered for 30 minutes with 98% (v/v) Ar and 2% (v/v) CO₂ as the sputter gas with the total Capman pressure maintained at 3 mtorr and the magnetron power set at 400 w RF. The Capman pressure is an instrumental parameter. The Capman pressure value is close to the pressure in the plasma chamber. The resulting carbon film was about 28 nm thick.

For the second layer on the disk, a magnesium target was sputtered for 3 minutes with 100% (v/v) Ar as the sputter gas with the total Capman pressure maintained at 3 mtorr and the magnetron power set at 400 w RF. The resulting film was about 125 nm thick.

For the third and final layer on the disk, a chromium target was sputtered for 5 minutes with 100% (v/v) Ar as the sputter gas with the total Capman pressure maintained at 4 mtorr and the magnetron power set at 400 w RF. The resulting film was about 46 nm thick.

The resulting disc had a polycarbonate support substrate, a carbon and carbon dioxide reactive material layer, a magnesium layer, and a chromium reflective layer.

### Example 4

### General Methods for Writing Data to Discs

Marks were made in the various discs using a Pulstec ODU1000 instrument (Pulstec Industrial Co., Ltd.; Hamamatsu-City; Japan) with a diode laser set at a wavelength of 650 nm. All writing was performed at 1× speed (3.49 m/second) and all writing was performed on single tracks unless otherwise noted. An HF signal was seen in all cases, and marks were positively observed using a microscope.

### Example 5

### Writing Data to Disc (65)

Writing to disc 65 was attempted at power levels of 6 mW to 60 mW, but no evidence of written data was observed. There was small evidence of writing at a power level of 75 mW. Writing of data was positively observed at the following power levels higher than 75 mW: 77.5 mW, 80 mW, 85 mW, 90 mW, and 100 mW. Both castle and multipulse strategies were used. The following mark lengths were successfully written at high power and verified by microscope: 5T (663 nm), 14T (1857 nm), and FCC (all pulse lengths).

### Example 6

### Writing Data to Disc (139)

Writing to disc 139 was performed at 100 mW power using a multipulse strategy at 33% duty. Mark lengths of 14t (1857 nm) were successfully written and verified by microscope.

### Example 7

### Summary of Writing Data to Discs

The following table summarizes the various discs, and the results obtained.

| Disc | Groove | Carbon | | Chromium | |
|---|---|---|---|---|---|
| number | depth | layer | Mg layer | layer | Data written |
| 65 | 170 | 28 | 125 | 92 | yes (at power ≧ |
| | | | | | 77.5 mW) |
| 139 | 60 | 14 | 125 | 46 | yes (at 100 mW |
| | | | | | power) |

### Example 8

### Analysis of Written Discs

Discs can be characterized by the amount of energy needed to record data, the quality and physical features of the written data (e.g., roundness, sidewall shape, presence or absence of berms), durability, and stability.

All of the compositions and/or methods and/or processes and/or apparatus disclosed and claimed herein can be made and executed without undue experimentation in light of the present disclosure. While the compositions and methods of this invention have been described in terms of preferred embodiments, it will be apparent to those of skill in the art that variations may be applied to the compositions and/or apparatus and/or processes and/or in the steps or in the sequence of steps of the methods described herein without departing from the concept and scope of the invention. More specifically, it will be apparent that certain agents that are both chemically and physically related may be substituted for the agents described herein while the same or similar results would be achieved. All such similar substitutes and modifications apparent to those skilled in the art are deemed to be within the scope and concept of the invention.

What is claimed is:

1. An optical information medium comprising:
at least one support substrate;
at least one magnesium metal layer; and
at least one reactive material layer.

2. The optical information medium of claim 1, wherein the magnesium metal layer consists of magnesium metal (Mg).

3. The optical information medium of claim 1, wherein the reactive material layer reacts with magnesium metal upon application of sufficient energy.

4. The optical information medium of claim 1, wherein the reactive material layer comprises an oxygenated hydrocarbon, polyvinyl alcohol, polycarbonate, poly(methylmethacrylate), poly[(methylmethacrylate)-co-(Disperse Red 1 methacrylate)], poly(methyl acrylate), poly(maleic acid), poly(DL-lactide), poly(propylene carbonate), poly(acrylic acid-co-maleic acid), a sugar, a monosaccharide, a polysaccharide, glucose, sucrose, lactose, D-glucuronic acid, sorbitol, cellulose, or nitrocellulose.

5. The optical information medium of claim 1, wherein the reactive material layer evolves a chemical that reacts with magnesium metal upon application of sufficient energy.

6. The optical information medium of claim 1, wherein:
the reactive material layer evolves a chemical that reacts with magnesium metal upon application of sufficient energy; and
the evolved chemical is carbon dioxide, carbon monoxide, ethanol, methanol, acetic acid, formic acid, dimethyl ether, or water.

7. The optical information medium of claim 1, wherein the magnesium metal layer facially contacts the reactive material layer.

8. The optical information medium of claim 1, wherein the support substrate facially contacts the reactive material layer.

9. The optical information medium of claim 1, wherein:
the support substrate facially contacts the reactive material layer; and
the reactive material layer facially contacts the magnesium metal layer.

10. The optical information medium of claim 1, further comprising at least one intervening layer between the support substrate and the reactive material layer.

11. The optical information medium of claim 1, wherein the support substrate comprises polycarbonate, polystyrene, aluminum oxide, polydimethyl siloxane, polymethylmethacrylate, silicon oxide, glass, fused silica, or mixtures thereof.

12. The optical information medium of claim 1, wherein the support substrate comprises polycarbonate.

13. The optical information medium of claim 1, further comprising at least one reflective layer.

14. The optical information medium of claim 1, further comprising at least one gas diffusion barrier layer.

15. The optical information medium of claim 1, further comprising at least one external protection layer.

16. The optical information medium of claim 1, comprising a first support substrate and a second support substrate.

17. The optical information medium of claim 1, wherein the support substrate and the reactive material layer are the same layer.

18. An optical information medium comprising:
a support substrate comprising polycarbonate;
a reactive material layer facially contacting the support substrate; and
a magnesium metal layer facially contacting the reactive material layer.

19. An optical information medium comprising:
a first support substrate comprising polycarbonate;
a gas diffusion barrier layer facially contacting the first support substrate;
a reactive material layer facially contacting the gas diffusion barrier layer;
a magnesium metal layer facially contacting the reactive material layer;
a reflective layer facially contacting the magnesium metal layer; and
a second support substrate facially contacting the reflective layer.

20. A method for preparing an optical information medium, the method comprising:
providing a support substrate;
applying a reactive material layer; and
applying a magnesium metal layer, such that the reactive material layer facially contacts the magnesium metal layer.

21. The method of claim 20, wherein the applying a magnesium metal layer step comprises sputtering, reactive sputtering, e-beam evaporation, laser ablation of a target, or chemical vapor deposition.

22. The method of claim 20, wherein the applying a reactive material layer step comprises sputtering, reactive sputtering, e-beam evaporation, laser ablation of a target, or chemical vapor deposition.

23. The method of claim 20, further comprising applying at least one intervening layer, such that the intervening layer facially contacts both the support substrate and the reactive material layer.

24. A method for preparing an optical information medium, the method comprising:
providing a first support substrate;
applying a reactive material layer;
applying a magnesium metal layer, such that the magnesium metal layer facially contacts the reactive material layer; and
applying a second support substrate.

25. A method of storing digital data, the method comprising:
providing an optical information medium comprising: at least one support substrate, at least one reactive material layer, and at least one magnesium metal layer; and
applying energy to sites in the magnesium metal layer to cause a detectable change in the magnesium metal layer.

26. The method of claim 25, further comprising detecting the change in the magnesium metal layer.
